(19) United States
(12) Patent Application Publication
(10) Pub. No.: US 2025/0233383 A1
(43) Pub. Date: Jul. 17, 2025

(54) OPTOELECTRONIC CHIP INTEGRATED SYSTEM AND MANUFACTURING METHOD THEREOF

(71) Applicant: ZHEJIANG LAB, Hangzhou City (CN)

(72) Inventors: Shaoliang YU, Hangzhou City (CN); Yong HU, Hangzhou City (CN); Qingyang DU, Hangzhou City (CN)

(73) Assignee: ZHEJIANG LAB, Hangzhou City, ZJ (CN)

(21) Appl. No.: 18/690,728

(22) PCT Filed: Nov. 23, 2023
(86) PCT No.: PCT/CN2023/133575

§ 371 Date: Mar. 9, 2024

(30) Foreign Application Priority Data
Sep. 21, 2023 (CN) 202311223543.5

(51) Int. Cl. H01S 5/00; H01S 5/02255; H01S 5/02325; H01S 5/183; H01S 5/185

(52) U.S. Cl. CPC H01S 5/0071; H01S 5/02255; H01S 5/02325; H01S 5/183; H01S 5/185

(57) ABSTRACT

The present application provides an optoelectronic chip integrated system and manufacturing method thereof. The optoelectronic chip integrated system includes a laser, a free-from surface coupler, and a chip. The laser is configured to emit a light beam. The free-form surface coupler is on a light path of the light beam emitted from the laser, and is configured to receive, reflect and shape the light beam. The chip is connected with the laser, and includes a waveguide structure, where the waveguide structure is connected with the free-form surface coupler, and is configured to receive the reflected and shaped light beam.

### CROSS-REFERENCE TO RELATED APPLICATIONS

This application is a national stage of international PCT Application No. PCT/CN2023/133575 filed on Nov. 23, 2023, and claims a priority to a Chinese Patent Application with the corresponding application number being 202311223543.5 and the application date being Sep. 21, 2023, the entire contents of which are incorporated herein by reference.

### TECHNICAL FIELD

The present application relates to the field of optoelectronic technology, and in particular, to an optoelectronic chip integrated system and manufacturing method thereof.

### BACKGROUND

Surface-emitting lasers have important application values in interconnection, computation, perception, and other fields, and their on-chip integration can effectively improve system stability, increase integration level, and reduce power consumption, which is an important direction for future development of optical systems.

However, at present, methods for interconnection between an on-chip laser and a silicon-based optoelectronic chip mainly include two hybrid integration methods based on grating diffraction and oblique reflection, both of which result in lower integration level and lower coupling efficiency.

### SUMMARY

The present application provides an optoelectronic chip integrated system and manufacturing method thereof, which can improve integration level and coupling efficiency of interconnection between a laser and a chip.

In an aspect of the present application, there is provided an optoelectronic chip integrated system, including: a laser configured to emit a light beam; a free-form surface coupler on a light path of the light beam emitted from the laser, and configured to receive, reflect and shape the light beam; and a chip connected with the laser, and including a waveguide structure, where the waveguide structure is connected with the free-form surface coupler, and is configured to receive the reflected and shaped light beam.

The optoelectronic chip integrated system provided in the present application improves integration level and coupling efficiency of interconnection between the laser and the chip by regulating the free-form surface coupler to connect the laser and the chip, so as to achieve high integration level, high stability, and high efficiency of the optoelectronic chip integrated system to meet requirements of the chip for input light beam.

Further, the free-form surface coupler includes an input end, an output end, and a free-form surface, where the input end is connected with the laser; at least a part of the output end is connected with the waveguide structure; the free-form surface is configured to convert a transmission direction of the light beam to be parallel to an extension direction of the waveguide structure, and convert a transmission mode of the light beam into a waveguide transmission mode, and the waveguide structure is configured to receive the light beam with the converted transmission direction and transmission mode.

Further, the chip further includes a cladding layer and a substrate layer, the waveguide structure is buried in the cladding layer, and the substrate layer is on a side of the cladding layer away from the laser; the chip further includes an etching groove, and the waveguide structure includes an input portion, where the etching groove is connected to the input portion of the waveguide structure and is depressed in a direction from the cladding layer to the substrate layer, the free-form surface coupler is in the etching groove, and the output end of the free-form surface coupler is connected with the input portion of the waveguide structure.

Further, the free-form surface coupler is formed by processing photoresist filled in the etching groove.

Further, the waveguide structure includes a tapered waveguide and a straight waveguide connected to the tapered waveguide, where the tapered waveguide is connected with the output end of the free-form surface coupler, and is configured to receive and transmit the light beam to the straight waveguide.

Further, the tapered waveguide includes a first end and a second end, where the first end is connected with the output end of the free-form surface coupler, and the second end is connected with the straight waveguide; a width of the tapered waveguide is on a trend of gradually increasing in a direction from the first end to the second end.

Further, a material for the waveguide structure includes at least one of a silicon waveguide, silicon nitride, or lithium niobate.

Further, the laser is invertedly soldered to a surface of the chip.

Further, the laser includes a substrate with a first bonding electrode; the chip further includes a second bonding electrode on a surface of the chip, and the second bonding electrode corresponds to the first bonding electrode for electrically connecting the chip and the laser.

Further, the laser includes a vertical-cavity surface-emitting laser, and the vertical-cavity surface-emitting laser includes a light emitting portion configured to emit the light beam, where the substrate is provided with the light emitting portion, the light emitting portion and the first bonding electrode are on opposite sides of the substrate, and an emission direction of the light beam is vertical to the substrate.

Further, the laser includes a horizontal-cavity surface-emitting laser, and the horizontal-cavity surface-emitting laser includes a light emitting portion and a reflecting portion, where the light emitting portion is configured to emit the light beam, and is on a side of the substrate vertical to an extension direction of the substrate, and an emission direction of the light beam is parallel to the extension direction of the substrate; the reflecting portion is configured to reflect the light beam and enable the light beam to be emitted in a direction vertical to the substrate.

Further, a section line of a free-form surface of the free-form surface coupler vertical to an extension direction of the waveguide structure is a curve line.

Further, the free-form surface includes a parabolic surface, and the input portion of the waveguide structure connected to the free-form surface coupler is close to a focal point of the parabolic surface.

Further, a section line of a free-form surface vertical to an extension direction of the waveguide structure is a straight line.

In another aspect of the present application, there is provided a method of manufacturing an optoelectronic chip integrated system, including: providing a chip including a waveguide structure; forming a free-form surface coupler on the chip, and connecting the free-form surface coupler with the waveguide structure; connecting a laser with the chip, such that the free-form surface coupler is on a light path of light beam emitted from the laser.

Further, forming the free-form surface coupler on the chip, and connecting the free-form surface coupler with the waveguide structure includes: etching an etching groove connected to an input portion of the waveguide structure; filling photoresist into the etching groove; machining the photoresist to form the free-form surface coupler.

Further, the laser includes a substrate with a first bonding electrode;
connecting the laser with the chip, such that the free-form surface coupler is on the light path of the light beam emitted from the laser, includes: preparing a second bonding electrode on a surface of the chip, where the second bonding electrode corresponds to the first bonding electrode; positioning the laser on the chip based on a position of the second bonding electrode; invertedly soldering the laser to the surface of the chip, such that the free-form surface coupler is on the light path of the light beam emitted from the laser.

### BRIEF DESCRIPTION OF THE DRAWINGS

The accompanying drawings, which are incorporated in and constitute a part of this specification, illustrate examples consistent with the present disclosure, and together with the description, serve to explain the principle of the disclosure.

FIG. 1 is a structural schematic diagram illustrating an embodiment of an optoelectronic chip integrated system according to the present application;

FIG. 2 is a schematic diagram illustrating a stereoscopic structure of the optoelectronic chip integrated system shown in FIG. 1;

FIG. 3 is a schematic diagram illustrating a principle of the optoelectronic chip integrated system shown in FIG. 1;

FIG. 4 is a structural schematic diagram illustrating another embodiment of the optoelectronic chip integrated system shown in FIG. 1;

FIG. 5 is a structural schematic diagram illustrating another embodiment of the optoelectronic chip integrated system shown in FIG. 1;

FIG. 6 is a structural schematic diagram illustrating another embodiment of the optoelectronic chip integrated system shown in FIG. 1;

FIG. 7 is a structural schematic diagram illustrating an embodiment of a waveguide structure of the optoelectronic chip integrated system shown in FIG. 1;

FIG. 8 is a schematic picture illustrating light field transmission simulation of the optoelectronic chip integrated system shown in FIG. 1;

FIG. 9 is a morphology picture illustrating laser beams emitted from a laser of the optoelectronic chip integrated system shown in FIG. 1 at an emitting end;

FIG. 10 is a morphology picture illustrating laser beams emitted from the laser of the optoelectronic chip integrated system shown in FIG. 1 at a receiving end;

FIG. 11 is a schematic diagram illustrating a relationship in which a coupling loss of the optoelectronic chip integrated system shown in FIG. 1 changes with a wavelength of a light beam;

FIG. 12 is a schematic diagram illustrating a relationship in which the coupling loss of the optoelectronic chip integrated system shown in FIG. 1 changes with deviation of a transverse position between a free-form surface coupler and a chip;

FIG. 13 is a schematic diagram illustrating a relationship in which the coupling loss of the optoelectronic chip integrated system shown in FIG. 1 changes with deviation of a longitudinal position between the free-form surface coupler and the chip;

FIG. 14 is a flowchart illustrating an embodiment of a method for manufacturing an optoelectronic chip integrated system according to the present application;

FIG. 15 is a flowchart illustrating an embodiment of step S200 in the manufacturing method shown in FIG. 14;

FIG. 16 is a flowchart illustrating an embodiment of step S300 in the manufacturing method shown in FIG. 14; and

FIG. 17 is a schematic diagram illustrating a process for manufacturing an optoelectronic chip integrated system using the manufacturing method shown in FIG. 14.

### DETAILED DESCRIPTION OF THE EMBODIMENTS

Examples will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present application. Rather, they are merely examples of apparatuses and methods consistent with some aspects of the present application as detailed in the appended claims.

The terms used in the present application are for the purpose of describing particular embodiments only, and are not intended to limit the present application. Unless otherwise defined, technical or scientific terms used in this application should have ordinary meaning as understood by one of ordinary skill in the art to which the application belongs. “First”, “second” and similar words used in the specification and claims of the present application do not represent any order, quantity or importance, but are used only to distinguish different components. Likewise, similar words such as “one”, “a” or “an” do not represent a quantity limit, but represent that there is at least one. “Plurality”, “multiple” or “several” means at least two. Unless otherwise indicated, similar words such as “front”, “rear”, “lower” and/or “upper” are only for convenience of description, and are not limited to one position or one spatial orientation. Similar words such as “including” or “comprising” mean that an element or an item appearing before “including” or “comprising” covers elements or items and their equivalents listed after “including” or “comprising”, without excluding other elements or items. Similar words such as “connect” or “connected with each other” are not limited to physical or mechanical connections, and may include electrical connections, whether direct or indirect.

Terms determined by “a/an”, “the” and “said” in their singular forms in the present application and the appended claims are also intended to include plural forms unless clearly indicated otherwise in the context. It should also be understood that the term “and/or” as used herein refers to and includes any or all possible combinations of one or more associated listed items.

The optoelectronic chip integrated system provided in the present application includes a laser, a free-from surface coupler, and a chip. The laser is configured to emit a light beam. The free-form surface coupler is on a light path of the light beam emitted from the laser, and is configured to receive, reflect and shape the light beam. The chip is connected with the laser, and includes a waveguide structure, where the waveguide structure is connected with the free-form surface coupler, and is configured to receive the reflected and shaped light beam.

The optoelectronic chip integrated system provided in the present application improves integration level and coupling efficiency of interconnection between the laser and the chip by regulating the free-form surface coupler to connect the laser and the chip, so as to achieve high integration level, high stability, and high efficiency of the optoelectronic chip integrated system to meet requirements of the chip for input light beam.

The method of manufacturing an optoelectronic chip integrated system provided in the present application includes: providing a chip including a waveguide structure; forming a free-form surface coupler on the chip, and connecting the free-form surface coupler with the waveguide structure; connecting a laser with the chip, such that the free-form surface coupler is on a light path of light beam emitted from the laser.

The optoelectronic chip integrated system and manufacturing method thereof in the present application will be described in detail below with reference to the accompanying drawings. In a case of no conflict, features in examples and embodiments described below can be combined with each other.

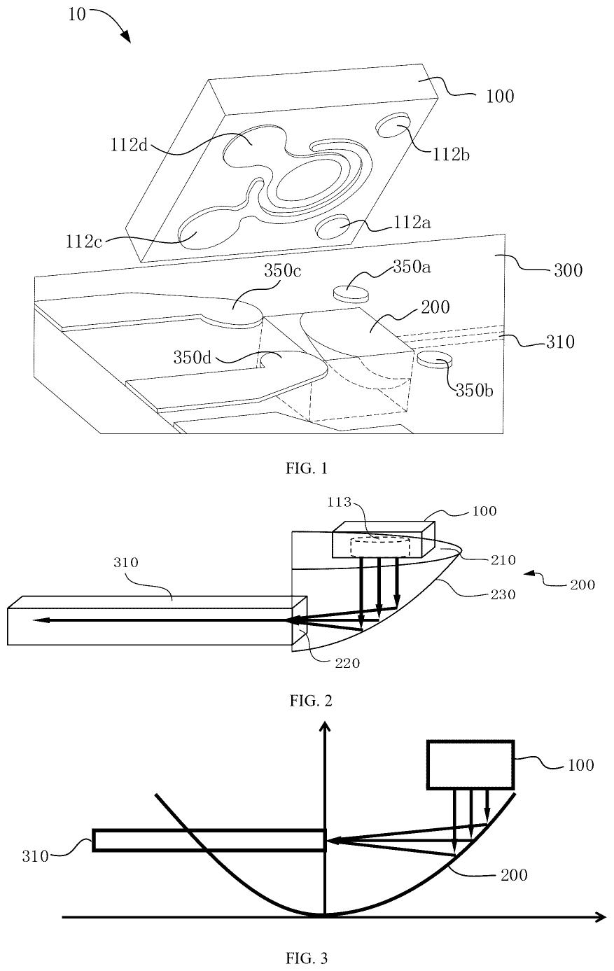

FIG. 1 is a structural schematic diagram illustrating an embodiment of an optoelectronic chip integrated system 10 according to the present application. The optoelectronic chip integrated system 10 in the embodiments of the present application includes a laser 100, a free-from surface coupler 200, and a chip 300. The laser 100 is configured to emit a light beam. The free-form surface coupler 200 is on a light path of the light beam emitted from the laser 100, and is configured to receive, reflect and shape the light beam. The chip 300 is connected with the laser 100, and includes a waveguide structure 310, where the waveguide structure 310 is connected with the free-form surface coupler 200, and is configured to receive the reflected and shaped light beam. The optoelectronic chip integrated system 10 in the embodiments of the present application improves integration level and coupling efficiency of interconnection between the laser 100 and the chip 300 by regulating the free-form surface coupler 200 to connect the laser 100 and the chip 300, so as to achieve high integration level, high stability, and high efficiency of the optoelectronic chip integrated system 10 to meet requirements of the chip 300 for input light beam.

FIG. 2 is a schematic diagram illustrating a stereoscopic structure of the optoelectronic chip integrated system 10 shown in FIG. 1. FIG. 3 is a schematic diagram illustrating a principle of the optoelectronic chip integrated system 10 shown in FIG. 1. In some embodiments, the free-form surface coupler 200 includes an input end 210, an output end 220, and a free-form surface 230, where the input end 210 is connected with the laser 100; at least a part of the output end 220 is connected with the waveguide structure 310; the free-form surface 230 is configured to convert a transmission direction of the light beam to be parallel to an extension direction of the waveguide structure 310, and convert a transmission mode of the light beam into a waveguide transmission mode, and the waveguide structure 310 is configured to receive the light beam with the converted transmission direction and transmission mode. As shown in FIG. 1 and FIG. 2, the input end 210 of the free-form surface coupler 200 may be a plane. The input end 210 may be flush with or higher than an upper surface of the chip 300. The output end 220 of the free-form surface coupler 200 may be a plane, so as to be connected with the waveguide structure 310. After the laser 100 emits the light beam, a size of light spots of the laser 100 is converted into a size of light spots in a waveguide mode of the chip 300 through total reflection and light beam convergence at an interface of the free-form surface 230 of the free-form surface coupler 200, and at the same time, the transmission direction of the light beam is converted into a direction of being parallel to the extension direction of the waveguide structure 310.

In some embodiments, the laser 100 includes a substrate 111 with a first bonding electrode 112. The chip 300 further includes a second bonding electrode 350 on a surface of the chip 300, and the second bonding electrode 350 corresponds to the first bonding electrode 112 one to one for electrically connecting the chip 300 and the laser 100. A number of the first bonding electrode 112 may be determined based on a number of bonding electrodes in a finished laser 100. As shown in FIG. 1, the number of the first bonding electrode 112 is 4, including a first bonding electrode 112a, a first bonding electrode 112b, a first bonding electrode 112c, and a first bonding electrode 112d. Correspondingly, a number and a position of the second bonding electrode 350 on the surface of the chip 300 correspond to a number and a position of the first bonding electrode 112, including a second bonding electrode 350a, a second bonding electrode 350b, a second bonding electrode 350c, and a second bonding electrode 350d, so as to prevent malposition of the second bonding electrode 350, and ensure stability and accuracy of interconnection between the laser 100 and the chip 300. The laser 100 may be coupled to the input end 210 of the free-form surface coupler 200, and ensuring good contact between the first bonding electrode 112 of the laser 100 and the second bonding electrode 350 on the chip 300, thus electrical connection between the laser 100 and the chip 300 is achieved. After the laser 100 emits the light beam, a size of light spots of the laser 100 is converted into a size of light spots in a waveguide mode of the optoelectronic chip 300 through total reflection and light beam convergence at an interface of the free-form surface 230 of the free-form surface coupler 200, and at the same time, the transmission direction of the light beam is converted into a direction of being parallel to the extension direction of the waveguide structure, thus achieving optical connection between the laser 100 and the chip 300. Materials for the first bonding electrode 112 and the second bonding electrode 350 include conductive metal.

In some embodiments, the laser 100 is invertedly soldered to the surface of the chip 300. The laser 100 is invertedly coupled to the free-form surface coupler 200 through invertedly soldering. In some embodiments, the laser 100 is invertedly soldered to the chip 300 prefabricated with the second bonding electrode 350 through heating and pressing, and ensuring good contact between the first bonding electrode 112 of the laser 100 and the second bonding electrode 350 on the chip 300. The invertedly soldering process is adopted for the laser 100 and the chip 300 in the embodiments of the present application, which can have better self-alignment and connection reliability through certain pressure and temperature. In some embodiments, the invertedly soldering process includes hot-pressure soldering, reflow soldering, epoxy resin photocuring, and anisotropic conductive adhesive.

The laser 100 may include a surface-emitting laser and/or a laser that emits vertically or at a certain angle after being packaged in other ways. The surface-emitting laser is a semiconductor laser whose light emission direction is vertical to the surface of the chip 300. Compared with edge-emitting lasers, surface-emitting lasers are easier to arrange in a two-dimensional array, allowing for construction of high-density surface array and adjustable multiple optical channels.

The surface-emitting lasers may include vertical-cavity surface-emitting lasers (VCSEL) and horizontal-cavity surface-emitting lasers (HCSEL). A resonator of VCSEL includes multiple epitaxial layers in a vertical direction, and has characteristics of high light beam quality, low lasing threshold, high differential efficiency, etc. A resonator of HCSEL includes a transverse micro-nano structure, and has characteristics of high output power, narrow spectral linewidth, small temperature drift, etc.

Methods for interconnection between a surface-emitting laser and a silicon-based optoelectronic chip currently mainly include two hybrid integration methods based on grating diffraction and oblique reflection. Based on the two interconnection methods, a degree of freedom of light beam mode field transformation is limited, making it difficult to achieve accurate mode field matching and impossible to achieve efficient integration, which restricts development of system integration. Momentum compensation methods based on grating diffraction has inherent limitations of multiple diffraction levels, and limited space for improving coupling efficiency, and is sensitive to a wavelength and polarization of laser light. A resonance wavelength of grating is significantly drifted due to influence of temperature, and its stability needs to be improved. Momentum compensation methods based on reflection focus mainly on an inclined plane, which can change a transmission direction, but lacks an ability to regulate mode field distribution, making it impossible to achieve accurate mode field matching. Therefore, it is difficult to achieve high coupling efficiency for the surface-emitting laser and the chip interconnected through the two methods. The optoelectronic chip integrated system 10 in the embodiments of the present application improves integration level and coupling efficiency of interconnection between the laser 100 and the chip 300 by regulating the free-form surface coupler 200 to connect the laser 100 and the chip 300, so as to achieve high integration level, high stability, and high efficiency of the optoelectronic chip integrated system 10 to meet requirements of the chip 300 for input light beam.

FIG. 4 is a structural schematic diagram illustrating another embodiment of the optoelectronic chip integrated system 10 shown in FIG. 1. In some embodiments, the laser 100 includes a vertical-cavity surface-emitting laser 120. The vertical-cavity surface-emitting laser 120 includes a light emitting portion 113 configured to emit the light beam. The substrate 111 is provided with the light emitting portion 113, the light emitting portion 113 and the first bonding electrode 112 are on opposite sides of the substrate 111, and an emission direction of the light beam is vertical to an extension direction of the substrate 111. In the embodiments, the vertical-cavity surface-emitting laser 120 serves as a light source of the optoelectronic chip integrated system 10. The vertical-cavity surface-emitting laser 120, after being powered on, emits Gaussian light beam vertically, and the emitted Gaussian light beam has good quality. In some embodiments, a radius of the beam waist of the Gaussian light beam is several micrometers, and the divergence angle thereof is several milliradians, the Gaussian light beam may be considered as nearly parallel transmission in the free-form surface coupler 200. The free-form surface coupler 200 is configured to convert vertically incident Gaussian light beam into waveguide transmission light beam parallel to a plane of the chip 300. On one hand, the transmission direction is changed by 90 degrees, and on the other hand, the Gaussian light beam with several micrometers is converted into a submicron waveguide transmission mode. The light beam emitted from the laser 100 may be vertical to the input end 210 of the free-form surface coupler 200 or be at any other incident angle, which is not limited in the present application.

Structural characteristics of the free-form surface 230 may be determined based on characteristics of incident light beam. When the incident light beam is vertical to the input end 210 of the free-form surface coupler 200, the free-form surface 230 changes the transmission direction of the light beam by 90 degrees to make the transmission direction of the light beam parallel to the extension direction of the chip 300, such that the waveguide structure 310 can receive the light beam with the changed transmission direction. Of course, the optoelectronic chip integrated system 10 in the embodiments of the present application is also suitable for coupling of light beam incident at other angles, as long as free-form surfaces 230 with different structures need to be constructed.

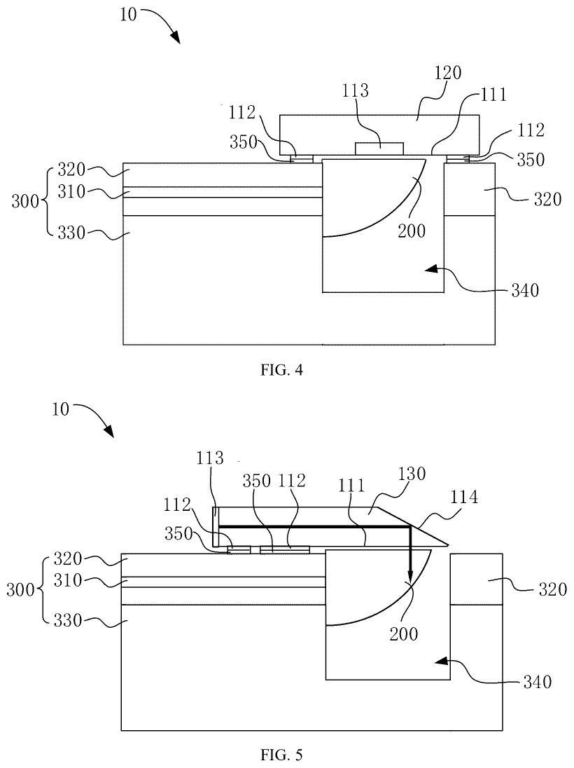

FIG. 5 is a structural schematic diagram illustrating another embodiment of the optoelectronic chip integrated system 10 shown in FIG. 1. In some embodiments, the laser 100 includes a horizontal-cavity surface-emitting laser 130. The horizontal-cavity surface-emitting laser 130 includes a light emitting portion 113 and a reflecting portion 114. The light emitting portion 113 is configured to emit the light beam, and is on a side of the substrate 111 vertical to an extension direction of the substrate 111, and an emission direction of the light beam is parallel to the extension direction of the substrate 111. The reflecting portion 114 is configured to reflect the light beam and enable the light beam to be emitted in a direction vertical to the substrate 111. It should be noted that a direction indicated by an arrow in FIG. 5 is the transmission direction of light beam. After the light beam is emitted from the light emitting portion 113, the transmission direction of the light beam is parallel to the extension direction of the waveguide structure 310. After the light beam is transmitted to the reflecting portion 114, their transmission direction is changed, and the light beam is finally emitted in a direction vertical to the substrate 111.

As shown in FIG. 5, in some embodiments, the input end 210 of the free-form surface coupler 200 may be in close proximity to the horizontal-cavity surface-emitting laser 130. In other embodiments, the input end 210 of the free-form surface coupler 200 may have a certain distance from the horizontal-cavity surface-emitting laser 130.

In some embodiments, the free-form surface 230 includes, but is not limited to, a parabolic surface, an extended curve surface of the parabolic surface, and other curve surfaces. As shown in FIG. 3, in an embodiment, the free-form surface 230 includes a parabolic surface. The light beam emitted from the laser 100 are reflected and converged by the parabolic surface, and after their transmission direction and transmission mode are converted, enter into the waveguide structure 310. The free-form surface coupler 200 includes a quadratic surface, which includes, but is not limited to, a parabolic surface, an extended structure of the parabolic surface, and other curve surface structures.

Referring to FIG. 4 and FIG. 5, based on the above embodiments, a section line of the free-form surface 230 vertical to an extension direction of the waveguide structure 310 is a curve line. In some embodiments, the free-form surface 230 includes a parabolic surface, and a side of the waveguide structure 310 connected to the free-form surface coupler 200 is close to a focal point of the parabolic surface. In this way, lights distributed at different positions of the laser 100 pass through the interface of the free-form surface 230 to undergo total reflection and turn to focus near a focal point of the free-form surface 230. A side of the waveguide structure 310 is near the focal point of the free-form surface 230, and the focal point is a position at which the light beam focus, thus achieving efficient collection of the Gaussian light beam emitted from the laser 100 onto the chip.

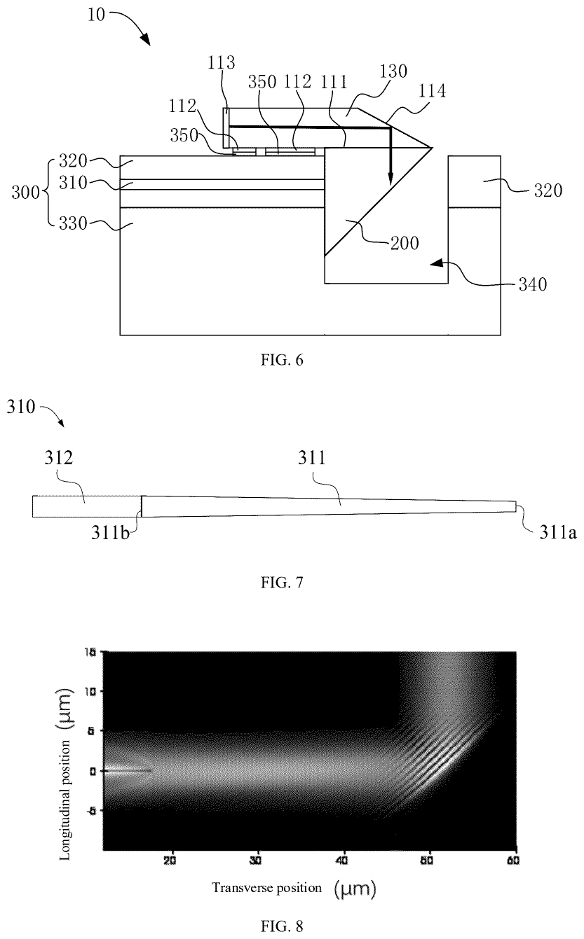

FIG. 6 is a structural schematic diagram illustrating another embodiment of the optoelectronic chip integrated system 10 shown in FIG. 1. In other embodiments, a section line of the free-form surface 230 vertical to an extension direction of the waveguide structure 310 is a straight line. In some embodiments, the free-form surface 230 may be a hyperbolic parabolic surface.

The chip 300 in the embodiments of the present application may include an all-optical chip 300 or an optoelectronic hybrid chip 300. The chip 300 may include any material. The waveguide structure 310 may include a straight waveguide 312, a tapered waveguide 311, and a multimode interference coupler. A specific structure of the waveguide structure 310 may be flexibly selected according to actual situation. In some embodiments, a material for the waveguide structure 310 include, but are not limited to, silicon waveguide, silicon nitride, lithium niobate waveguide, and other materials.

In some embodiments, the chip 300 further includes a cladding layer 320 and a substrate layer 330, the waveguide structure 310 is buried in the cladding layer 320, and the substrate layer 330 is on a side of the cladding layer 320 away from the laser 100. The chip 300 further includes an etching groove 340, and the waveguide structure 310 includes an input portion. The etching groove 340 is connected with the input portion of the waveguide structure and is depressed in a direction from the cladding layer 320 to the substrate layer 330. The free-form surface coupler 200 is in the etching groove 340, and the output end 220 of the free-form surface coupler 200 is connected with the input portion of the waveguide structure 310. In some embodiments, a material for the cladding layer 320 may include silicon dioxide, and a material for the substrate layer 330 may include silicon.

FIG. 7 is a structural schematic diagram illustrating an embodiment of a waveguide structure 310 of the optoelectronic chip integrated system 10 shown in FIG. 1. In some embodiments, the waveguide structure 300 includes a tapered waveguide 311 and a straight waveguide 312 connected with the tapered waveguide 311. The tapered waveguide 311 is connected with the output end 220 of the free-form surface coupler 200, and is configured to receive and transmit the light beam to the straight waveguide 312. The tapered waveguide 311 is configured to further convert the mode field converted by the free-form surface 230 into the waveguide transmission mode in the chip 300 without loss.

In some embodiments, the tapered waveguide 311 includes a first end 311a and a second end 311b. The first end 311a is connected with the output end 220 of the free-form surface coupler 200, and the second end 311b is connected with the straight waveguide 312. A width of the tapered waveguide 311 is on a trend of gradually increasing in a direction from the first end 311a to the second end 311b. The first end 311a of the tapered waveguide 311, i.e., a side with a smallest width, is closely coupled to the output end 220 of the free-form surface coupler 200, which is near a position of a focal point of the free-form surface coupler 200. A length and a minimum width of the tapered waveguide 311 may be determined based on a specific material and a radius of the beam waist of the light spot emitted from a surface-emitting laser.

In some embodiments, the free-form surface coupler 200 is formed by machining in the etching groove 340 filled with photoresist. A process of preparing the free-form surface coupler 200 includes, but is not limited to, two-photon lithography, grayscale lithography, nanoimprinting, and other micro-nano machining processes. In some embodiments, the interface of the free-form surface 230 may be placed in an air environment through an etching process to increase a refractive index difference between the free-form surface 230 and the environment. A material for photoresist may include polymers. An edge length of the etching groove 340 is in the order of hundred micrometers.

The laser 100 of the optoelectronic chip integrated system 10 in the embodiments of the present application is invertedly coupled to the free-form surface coupler 200 through invertedly soldering, and it is required to ensure good contact between a bonding electrode of a surface-emitting laser and a bonding electrode on the chip 300, such that Gaussian light beam with a diameter being in the order of several micrometers can be radiated under driving of voltage; the radiated Gaussian light beam is vertically incident from the input end of the free-form surface coupler 200 into the free-form surface coupler 200. Since a divergence angle of the Gaussian light beam is smaller, the light beam is transmitted almost in parallel in the free-form surface coupler 200; according to characteristics of light beam being transmitted within the parabolic surface, the light beam incidents in parallel, after being reflected on the parabolic surface, focus on the focal point of the parabolic surface; the input portion of the waveguide structure 310 in the chip 300 is at a position of the focal point of the parabolic surface of the free-form surface coupler 200, such that most of light reflected by the free-form surface coupler 200 are collected by the waveguide structure 310; from the perspective of transmission mode, the vertically incident Gaussian light beam in the order of micrometers is converted into a waveguide mode of parallel waveguide transmission through coupling of the free-form surface 230, thus achieving efficient interconnection between the laser 100 and the chip 300.

In an embodiment, a silicon nitride waveguide is adopted for the waveguide structure 310, and the waveguide structure 310 is buried in a silicon oxide environment; the first end 311a of the tapered waveguide 311, i.e., a minimum waveguide width, is 0.15 μm. The vertical-cavity surface-emitting laser 120 is used as the laser 100, with a radius of the beam waist being 4 μm. The parabolic surface is adopted for the free-form surface coupler 200, with a focal length of a parabolic line being p/2-26 μm (parabolic equation). The etching groove 340 is machined through an etching process, with an edge length being 100 μm, and an etching depth being 140 μm.

On the basis of the above embodiments, a Finite Difference Time Domain (FDTD) method is adopted to simulate light field transmission between the laser 100 and the chip 300. In simulation parameter design, Gaussian light beam is used as a light source, with a wavelength of the Gaussian light beam set to be 1550 nm, and the Gaussian light beam is vertically incident into the free-form surface coupler 200; a width of the first end 311a of the waveguide structure 310 in the chip 300 is 150 nm, a height thereof is 220 nm, and a regional refractive index of the free-form surface coupler 200 is 1.4714.

FIG. 8 is a schematic picture illustrating light field transmission simulation of the optoelectronic chip integrated system 10 shown in FIG. 1. As shown in FIG. 8, Gaussian light beam emitted from the vertical-cavity surface-emitting laser 120 are reflected at the interface of the free-form surface coupler 200, well converting the transmission direction of the Gaussian light beam to be parallel to the extension direction of the waveguide structure 310.

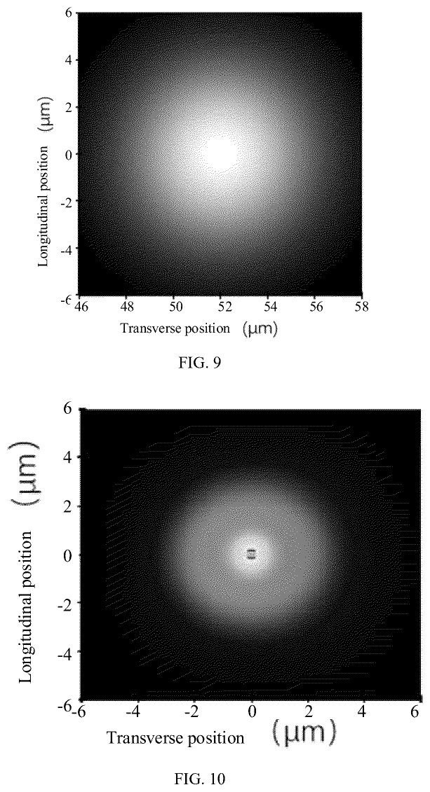

FIG. 9 is a morphology picture illustrating light beam emitted from a laser 100 of the optoelectronic chip integrated system 10 shown in FIG. 1 at an emitting end. FIG. 10 is a morphology picture illustrating light beam emitted from the laser 100 of the optoelectronic chip integrated system 10 shown in FIG. 1 at a receiving end. As shown in FIG. 9 and FIG. 10, through reflection and convergence of the free-form surface coupler 200, a size of a light spot of a light beam is well converted into a mode that supports low loss transmission in the waveguide structure 310, indicating good performance of the free-form surface coupler 200 in spot-size conversion.

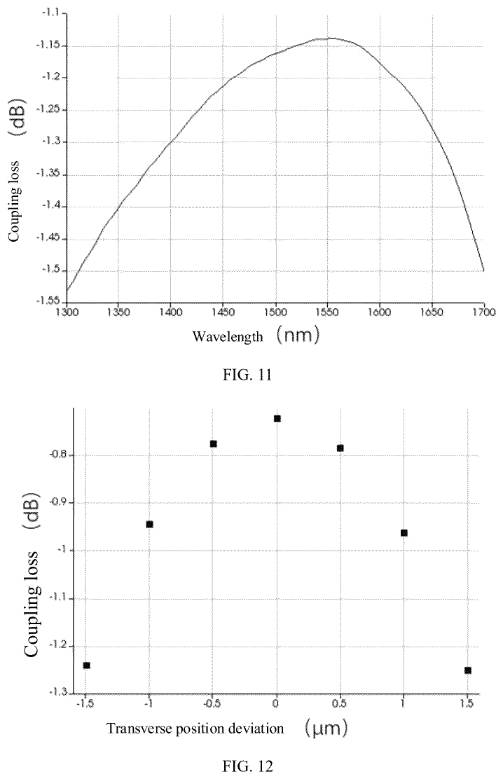

FIG. 11 is a schematic diagram illustrating a relationship in which a coupling loss of the optoelectronic chip integrated system 10 shown in FIG. 1 changes with wavelengths of a light beam. As shown in FIG. 11, it can be seen that, within an entire waveband range of 1300 nm-1700 nm (spanning wavebands O, E, S, C, L and U), for TE mode, waveguide loss is below 1.5 dB, and a bandwidth of 1 dB exceeds 300 nm, indicating that the reflective-based free-form surface coupler 200 is independent of wavelength and polarization, and has unique advantages compared to a diffractive grating coupler.

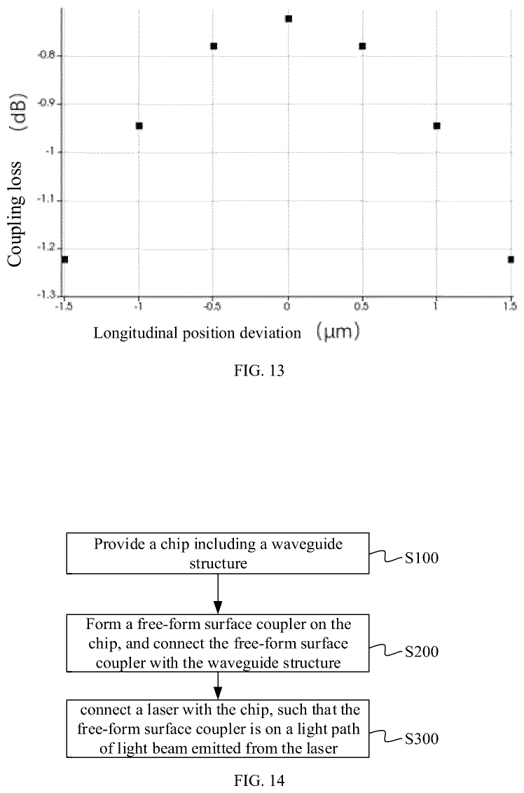

FIG. 12 is a schematic diagram illustrating a relationship in which the coupling loss of the optoelectronic chip integrated system 10 shown in FIG. 1 changes with deviation of a transverse position between a free-form surface coupler 200 and a chip 300. FIG. 13 is a schematic diagram illustrating a relationship in which the coupling loss of the optoelectronic chip integrated system 10 shown in FIG. 1 changes with deviation of a longitudinal position between the free-form surface coupler 200 and the chip 300. As shown in FIG. 12 and FIG. 13, alignment tolerance of the free-form surface coupler 200 is simulated by transforming the relationship in which the coupling loss changes with the position. According to FIG. 12, it can be known that alignment tolerance of a plane coupled to the free-form surface 230 is ±2 μm. In addition, since the laser 100 is invertedly coupled to an upper end of the free-form surface coupler 200, alignment tolerance outside the plane may be ignored, indicating that the structure of the free-form surface coupler 200 can have good alignment tolerance for machining process. According to FIG. 13, it can be known that a bonding process between the laser 100 and the chip 300 is not sensitive to a distance between the laser 100 and the chip 300 in a vertical direction, that is, alignment tolerance in the vertical direction is larger, which is a big advantage of the optoelectronic chip integrated system 10 in the embodiments of the present application.

FIG. 14 is a flowchart illustrating an embodiment of a method for manufacturing an optoelectronic chip integrated system according to the present application. The optoelectronic chip integrated system in the embodiments of the present application includes steps $100 to S300.

At step S100, a chip including a waveguide structure is provided.

At step S200, a free-form surface coupler is formed in the chip, and the free-form surface coupler is connected with the waveguide structure.

At step S300, a laser is connected with the chip, such that the free-form surface coupler is on a light path of light beam emitted from the laser.

It should be noted that the chip in the embodiments of the present application may include an all-optical chip or an optoelectronic hybrid chip. The chip may include any material.

In some embodiments, the chip further includes a cladding layer and a substrate layer. The waveguide structure is buried in the cladding layer, and the substrate layer is on a side of the cladding layer away from the laser. Based on the above embodiments, the free-form surface coupler can be prepared on the silicon-based substrate layer of the chip to be connected.

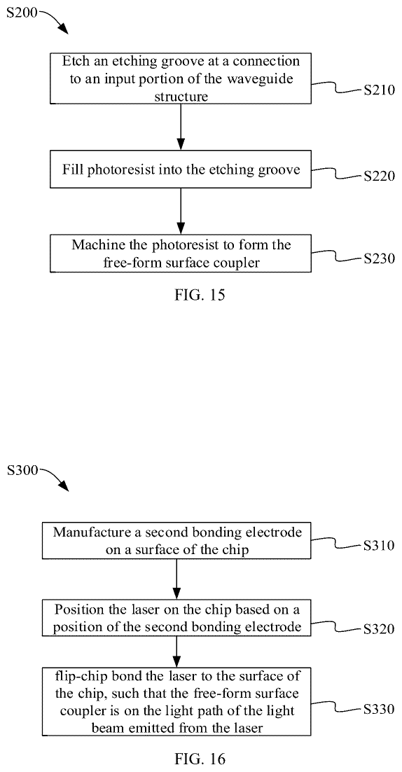

FIG. 15 is a flowchart illustrating an embodiment of step S200 in the manufacturing method shown in FIG. 14. In some embodiments, as shown in FIG. 15, step S200 in the method of manufacturing the optoelectronic chip integrated system in the present application may include steps S210 to S230:

At step S210, an etching groove connected to an input portion of the waveguide structure is etched.

At step S220, photoresist is filled into the etching groove.

At step S230, the photoresist is machined to form the free-form surface coupler.

In some embodiments, in step S210, the etching groove may be etched at the connection to the input portion of the waveguide structure of the chip through a deep etching process, and the input portion of the waveguide structure is at an edge of the etching groove. An edge length of the etching groove is in the order of hundred micrometers.

In some embodiments, in step S220, the photoresist may be spin-coated in a deep etching groove, and the free-form surface coupler with a parabolic surface may be formed layer by layer in polymer photoresist filled in the etching groove by processes of overlaying and double-photon lithography. After the free-form surface coupler is regionally exposed, non-exposed regions may be etched off through the etching process to expose an outer side of a free-form surface of the free-form surface coupler to an air environment, so as to increase a refractive index difference between the free-form surface and the environment. A material for photoresist includes polymer.

FIG. 16 is a flowchart illustrating an embodiment of step S300 in the manufacturing method shown in FIG. 14. In some embodiments, as shown in FIG. 16, step S300 in the method of manufacturing the optoelectronic chip integrated system in the present application may include steps S310 to S330.

At step S310, a second bonding electrode is manufactured on a surface of the chip, where the second bonding electrode corresponds to a first bonding electrode.

At step S320, the laser is positioned on the chip based on a position of the second bonding electrode.

At step S330, the laser is invertedly soldered to the surface of the chip, such that the free-form surface coupler is on the light path of the light beam emitted from the laser.

In the embodiments, the first bonding electrode and the second bonding electrode mate with each other to achieve precise positioning of the laser and the chip.

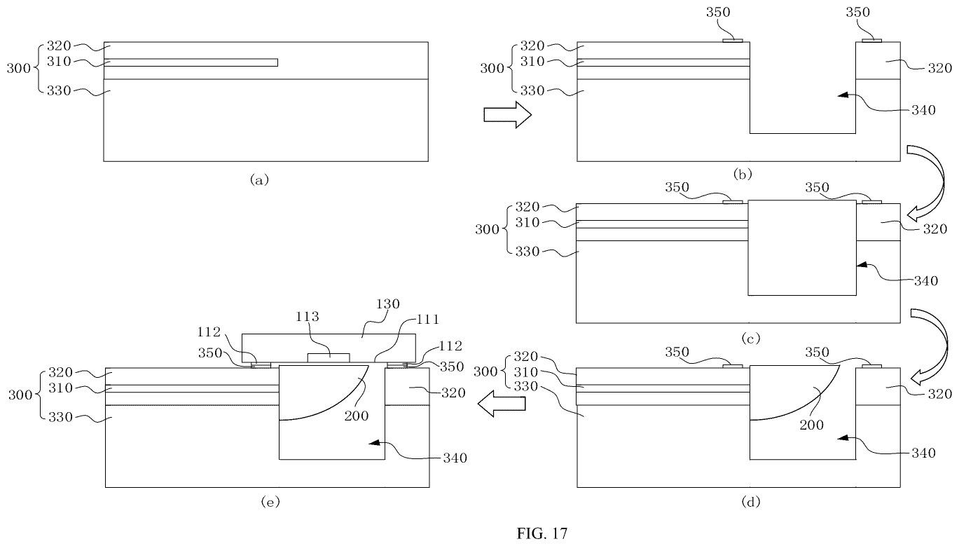

FIG. 17 is a schematic diagram illustrating a process for manufacturing an optoelectronic chip integrated system 10 using the manufacturing method shown in FIG. 14. As shown in FIG. 17 (a), the process of manufacturing the optoelectronic chip integrated system 10 includes providing a chip 300, which includes a waveguide structure 310, a cladding layer 320, and a substrate layer 330. The waveguide structure 310 is buried in a silicon oxide environment. As shown in FIG. 17 (b), the process of manufacturing the optoelectronic chip integrated system 10 further includes etching an etching groove 340 connected to an input portion of the waveguide structure 310. A depth of the etching groove 340 may be greater than or equal to a depth of the waveguide structure 310, so as to connect the free-form surface coupler 200 with the waveguide structure 310. A side of the etching groove 340 is connected with the input portion of the waveguide structure 310. As shown in FIG. 17 (c), the process of manufacturing the optoelectronic chip integrated system 10 further includes spinning photoresist into the etching groove 340. As shown in FIG. 17 (d), the process of manufacturing the optoelectronic chip integrated system 10 includes forming the free-form surface coupler 200 with a parabolic surface layer by layer in polymer photoresist filled in the etching groove 340. After the free-form surface coupler 200 is regionally exposed, non-exposed regions may be etched off through an etching process to expose an outer side of a free-form surface 230 of the free-form surface coupler 200 to an air environment. As shown in FIG. 17 (e), the process of manufacturing the optoelectronic chip integrated system 10 includes invertedly soldering the laser 100 to a surface of the chip 300, such that the free-form surface coupler 200 is on a light path of light beam emitted by the laser 100.

For method embodiments, since they basically correspond to the apparatus embodiments, reference may be made to the partial description of the apparatus embodiments. The method embodiments and apparatus embodiments are complementary to each other

The above are only some embodiments of the present application, which are not intended to limit the application. Any modification, equivalent replacement, improvement, etc. made within the spirit and principle of the application shall be included in the protection scope of the application.

1. An optoelectronic chip integrated system, comprising:
a laser configured to emit a light beam;
a free-form surface coupler on a light path of the light beam emitted from the laser, and configured to receive, reflect and shape the light beam; and
a chip connected with the laser, and comprising a waveguide structure, wherein the waveguide structure is connected with the free-form surface coupler, and is configured to receive the reflected and shaped light beam.

2. The optoelectronic chip integrated system according to claim 1, wherein the free-form surface coupler comprises an input end, an output end, and a free-form surface, wherein the input end is connected with the laser; at least a part of the output end is connected with the waveguide structure; the free-form surface is configured to convert a transmission direction of the light beam to be parallel to an extension direction of the waveguide structure, and convert a transmission mode of the light beam into a waveguide transmission mode, and the waveguide structure is configured to receive the light beam with the converted transmission direction and transmission mode.

3. The optoelectronic chip integrated system according to claim 2, wherein the chip further comprises a cladding layer and a substrate layer, the waveguide structure is buried in the cladding layer, and the substrate layer is on a side of the cladding layer away from the laser; and
the chip further comprises an etching groove, and the waveguide structure comprises an input portion, wherein the etching groove is connected with the input portion of the waveguide structure and is depressed in a direction from the cladding layer to the substrate layer, the free-form surface coupler is in the etching groove, and the output end of the free-form surface coupler is connected with the input portion of the waveguide structure.

4. The optoelectronic chip integrated system according to claim 3, wherein the free-form surface coupler is formed by processing photoresist filled in the etching groove.

5. The optoelectronic chip integrated system according to claim 3, wherein the waveguide structure comprises a tapered waveguide and a straight waveguide connected to the tapered waveguide, wherein the tapered waveguide is connected with the output end of the free-form surface coupler, and is configured to receive and transmit the light beam to the straight waveguide.

6. The optoelectronic chip integrated system according to claim 5, wherein the tapered waveguide comprises a first end and a second end, wherein the first end is connected with the output end of the free-form surface coupler, and the second end is connected with the straight waveguide; and a width of the tapered waveguide is on a trend of gradually increasing in a direction from the first end to the second end.

7. The optoelectronic chip integrated system according to claim 1, wherein a material for the waveguide structure comprises at least one of a silicon waveguide, silicon nitride, or lithium niobate.

8. The optoelectronic chip integrated system according to claim 1, wherein the laser is invertedly soldered to a surface of the chip.

9. The optoelectronic chip integrated system according to claim 1, wherein the laser comprises a substrate with a first bonding electrode; the chip further comprises a second bonding electrode on a surface of the chip, and the second bonding electrode corresponds to the first bonding electrode for electrically connecting the chip and the laser.

10. The optoelectronic chip integrated system according to claim 9, wherein the laser comprises a vertical-cavity surface-emitting laser, and the vertical-cavity surface-emitting laser comprises a light emitting portion configured to emit the light beam, wherein the substrate is provided with the light emitting portion, the light emitting portion and the first bonding electrode are on opposite sides of the substrate, and an emission direction of the light beam is vertical to the substrate.

11. The optoelectronic chip integrated system according to claim 9, wherein the laser comprises a horizontal-cavity surface-emitting laser, and the horizontal-cavity surface-emitting laser comprises a light emitting portion and a reflecting portion, wherein the light emitting portion is configured to emit the light beam, and is on a side of the substrate vertical to an extension direction of the substrate, and an emission direction of the light beam is parallel to the extension direction of the substrate; the reflecting portion is configured to reflect the light beam and enable the light beam to be emitted in a direction vertical to the substrate.

12. The optoelectronic chip integrated system according to claim 10, wherein a section line of a free-form surface of the free-form surface coupler vertical to an extension direction of the waveguide structure is a curve line.

13. The optoelectronic chip integrated system according to claim 12, wherein the free-form surface comprises a parabolic surface, and a side of the waveguide structure connected to the free-form surface coupler is close to a focal point of the parabolic surface.

14. The optoelectronic chip integrated system according to claim 10, wherein a section line of a free-form surface of the free-form surface coupler vertical to an extension direction of the waveguide structure is a straight line.

15. A method of manufacturing an optoelectronic chip integrated system, comprising:
providing a chip comprising a waveguide structure;
forming a free-form surface coupler on the chip, and connecting the free-form surface coupler with the waveguide structure; and
connecting a laser with the chip, such that the free-form surface coupler is on a light path of light beam emitted from the laser.

16. The manufacturing method according to claim 15, wherein forming the free-form surface coupler on the chip, and connecting the free-form surface coupler with the waveguide structure comprises:
etching an etching groove connected to an input portion of the waveguide structure;
filling photoresist into the etching groove; and
machining the photoresist to form the free-form surface coupler.

17. The manufacturing method according to claim 15, wherein the laser comprises a substrate with a first bonding electrode;
connecting the laser with the chip, such that the free-form surface coupler is on the light path of the light beam emitted from the laser, comprises:
manufacturing a second bonding electrode on a surface of the chip, wherein the second bonding electrode corresponds to the first bonding electrode;
positioning the laser on the chip based on a position of the second bonding electrode; and
electrically connecting the second bonding electrode with the first bonding electrode, such that the laser is invertedly soldered to the surface of the chip, and the free-form surface coupler is on the light path of the light beam emitted from the laser.

18. The optoelectronic chip integrated system according to claim 11, wherein a section line of a free-form surface of the free-form surface coupler vertical to an extension direction of the waveguide structure is a curve line.

19. The optoelectronic chip integrated system according to claim 11, wherein a section line of a free-form surface of the free-form surface coupler vertical to an extension direction of the waveguide structure is a straight line.
